(19) United States
(12) Patent Application Publication
(10) Pub. No.: US 2012/0154994 A1
(43) Pub. Date: Jun. 21, 2012

(54) HOUSING WITH ASSISTED OPENING

(75) Inventor: Claude Lambert, Saint-Cloud (FR)

(73) Assignee: QUALIPAC SA, Neuilly-sur-Seine (FR)

(21) Appl. No.: 13/148,744

(22) PCT Filed: Dec. 18, 2009
(86) PCT No.: PCT/FR2009/001463

§ 371 Date: Mar. 6, 2012

(30) Foreign Application Priority Data
Feb. 10, 2009 (FR) 0950825

(51) Int. Cl. H05K 5/00; B65D 43/16; B65D 13/00

(52) U.S. Cl. 361/679.01; 206/1.5

(57) ABSTRACT

The present invention relates to a housing comprising a cover, a base, a plate inserted between said cover and said base, said cover being rotatably hinged relative to said plate by means of a hinge, a locking system rigidly connecting said cover and said base in a closed position, characterised in that said plate is slidably mounted on said base so as to enable a translation movement of said cover causing the locking system to unlock.

### PRIORITY CLAIM

The present application is a National Phase entry of PCT Application No. PCT/FR2009/001463, filed Dec. 18, 2009, which claims priority from French Application No. 0950825, filed Feb. 10, 2009, the disclosures of which are hereby incorporated by reference herein in their entirety.

### TECHNICAL FIELD

The present invention relates to a housing with enhanced opening, particularly suitable for containing a cosmetic product, an ordinary object or a portable electronic apparatus. In particular, the invention hereof includes a housing formed by two parts articulated by means of a hinge, one of the two parts constituting the cover and the other part constituting the bottom of the housing, in particular applicable in order to contain cosmetic products. The bottom of such a housing may be formed in a known manner from a single hollow piece creating an interior space.

### BACKGROUND ART

It is known to close housings with the assistance of a fastening system comprising an element arranged on the edge of the cover and an element arranged on the bottom of the housing opposite the hinge. The element arranged on the edge of the cover may be a hook that cooperates with a joint opening of the bottom of the housing. The joint part of the bottom may be created by a supplementary piece, often referred to as a drawer, which is prone to slide between guides, or in a channel, formed in the bottom of the housing. The drawer slides by manual action on an actuator arranged on the drawer and accessible from the exterior, by an elastic return arranged on the drawer permitting the drawer to return to the rest position thereof.

Generally, opening this type of housing is not always easy to use for the user, given the risk of the drawer snagging or scraping during the sliding movement thereof, and given that the elastic return does not provide for a sufficient trajectory for the drawer, causing difficulties in opening the housing. Moreover, this type of design necessitates the execution of a plurality of complex pieces, particularly in the case of the elastic return, which is a particular arrangement of the bottom of the housing for the drawer to slide that gives rise to an increased cost of production.

A housing of a design that is both simple and aesthetically pleasing, obviating the need to use complex pieces while also reducing the number of pieces required in the preparation of the housing, would provide distinct advantages.

### SUMMARY OF THE INVENTION

To this end, the invention proposes a housing comprising a cover, a base, a plate inserted between the cover and the base, wherein the cover is rotatably articulated relative to the plate by means of a hinge, and a locking system fixedly connecting the cover and the base in a closed position. The plate is slidably mounted on said base so as to enable a translation movement of said cover causing the locking system to unlock. Force applied to the cover causes the plate to slide from an initial position towards a secondary opening position.

The designation “plate” refers to an element allowing in particular the support or integration of containers intended to receive cosmetic products, objects such as for example eyewear, watches, jewelry or leather goods, or components of a portable electronic apparatus such as a telephone, a personal music player, an mp3 reader or a navigator. Such containers may also be integrated into the plate.

The housing hereof obviates the need to use a complex closing mechanism, and simplifies the shape of the different parts constituting the housing, while also proposing an opening mechanism that is aesthetically pleasing and easy to use for the user.

The housing according to the invention may also comprise, in addition to the principle characteristics previously mentioned in the preceding paragraph, one or a plurality of the following characteristics, taking individually or according to any technically possible combination:
the fastening system is formed by a projection arranged on the base, cooperating with a hook arranged on the cover;
the base comprises an impression cooperating with a projection of the plate, such that the plate slides into the impression;
the housing comprises an elastic return suitable for returning the position of the plate into an initial position;
the hinge comprises an elastic element and/or a retarder for initializing and/or braking the rotation of the cover;
the hinge comprises a stop that blocks the rotation of said cover;
the plate comprises at least one compartment suitable for receiving a cosmetic product;
the housing is suitable for receiving one or a plurality of objects, in particular eyewear, mirrors, jewelry or leather goods;
the plate and/or the cover of the housing comprise components of a portable electronic apparatus, in particular a portable telephone, a navigator, a personal music player or an mp3 reader;
the housing is made from a plastic material, from Zamak, from metal or from alloys or a combination of those materials.

### BRIEF DESCRIPTION OF THE DRAWINGS

Other characteristics and advantages of the invention will become more evident from the description of an embodiment given below, provided for information only and in no way meant to be a limitation, with reference to the attached figures, among which:

FIG. 1 represents a longitudinal perspective view of a housing suitable for containing a cosmetic product, according to the invention, in a closed position;

FIG. 2 represents a partial, longitudinal perspective view of a housing suitable for containing a cosmetic product, according to the invention, in a locked position;

FIG. 3 represents a longitudinal perspective view of a housing suitable for containing a cosmetic product, according to the invention, in an open position.

### DETAILED DESCRIPTION OF THE DRAWINGS

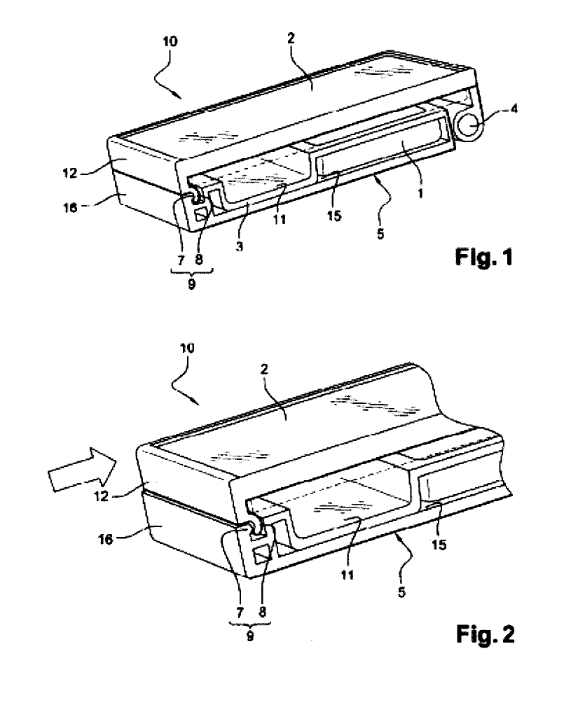

The housing suitable for containing a cosmetic product, illustrated in FIGS. 1, 2 and 3, is designated in the entirety thereof by the reference 10. In each figure, shared elements bear the same reference numerals. The concepts of direction and position, such as “interior,” “exterior,” “front,” “rear,” . . . are mentioned in the classical sense of arranging different elements when actually placed inside a housing.

The housing 10 is formed with a cover 2 mounted rotatably by means of a hinge 4 relative to a plate 3. A compartment 1, suitable for containing a cosmetic product, for example foundation, is incised onto the plate 3.

According to the illustrated embodiment, the plate 3 comprises in addition a second compartment 11 of a depth adapted to containing applicators, for example brushes.

According to different embodiments of the invention, the plate 3 of the housing 10 may comprise different compartments of variable depths intended to contain various cosmetic products or other associated elements.

The housing 10 further comprises a base 5 formed by a flat rectangular surface 15, provided by two flat lateral walls 18 and a front wall 16.

On the side of the base 5, opposite the hinge 4, the front wall 16 comprises an indentation in the middle of the upper edge thereof, in which a “half-round” protuberance 7 creates a projection towards the interior of the base 5.

The plate 5 is mounted to be slidable in the longitudinal direction of the housing 10 in the interior of the base 5, wherein the lateral walls 18 and front wall 16 thereof limit the movement of the plate 3.

The plate 3 moves by sliding on the base 5, between an initial position in which the plate 3 is in contact with the front wall 16 of the base 5, and a secondary position defined by a stop on the interior of the housing between the base 5 and the plate 3.

The plate 3 is on the base 5, by, for example, a projection of the plate 3 which moves in a groove of the base. According to an advantageous mode of the invention, the plate 3 comprises two pins on the outer surfaces of the lateral walls that cooperate with longitudinal grooves, created on the lateral walls 18 of the base in the sliding direction of the plate 3, the plate 3 being pre-assembled by force on the base 5.

Sliding the plate 3 causes the cover 2 to move, where the hinge 4 provides a coupling between the plate 3 and the cover 2.

In the closed position of the housing 10, illustrated in FIG. 1, the plate 3 is in the initial position thereof, in which the front wall of the plate 3 is in contact with the front wall 16 of the base 5.

The cover 2 is formed by a rectangular flat surface 21, provided with flat lateral walls 22, a front wall 12 and a rear wall 24 perpendicular to the flat surface 21.

According to one embodiment of the invention, the flat surface 21 may comprise a reflecting surface such as a thin mirror, which entirely or partially covers the flat surface 21.

On the side of the cover 2, opposite the hinge 4, the font wall 12 comprises, on the middle of the lower edge 23 thereof, a projection 8 incised therein, forming a hook, wherein the concave part thereof is directed towards the exterior of the cover 2 so as to cooperate with the “half-round” protuberance 7.

In the closed position, illustrated in FIG. 1, the hook 8 and the protuberance 7 cooperate and thus form a closing means 9 of the housing 10 so as to fixedly connect the cover 2 to the base 5. When the user wishes to open the housing 10, the user presses on the front wall 12 of the cover 2 in parallel with the mean plane of the housing 10 and towards the rear of the housing 10—that is, towards the hinge 4.

The force exerted on the cover 2 causes the plate 3 to slide from the original position thereof, in which the front wall thereof is in contact with the front wall 17 of the base, towards a secondary open position.

When sliding towards the rear of the plate 3, the closing assembly 9, created by the hook 8 and the protuberance 7, disengage so as to free the cover 2 and open the housing 10. FIG. 2 in particular illustrates the disengagement of the closing assembly 9 by the movement of the cover 2 and the plate 3 towards the rear of the housing 10.

The rotation of the cover 2 of the housing 10 is achieved without external intervention, for example by an elastic element such as coiled springs cooperating with the hinge 4, the rotation of the cover 2 being braked by the retarder constructed in the hinge 4 so as to generate an aesthetically pleasing opening and the pleasing impression of fluidity and grace for the user.

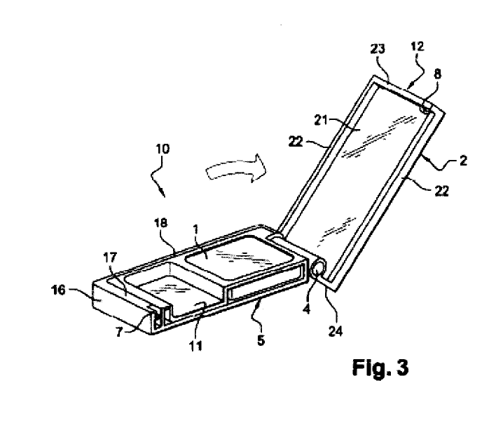

The rotation of the cover 2 is stopped by a stop integrated into the hinge 4, the aforementioned elastic element making it possible to maintain the housing 10 in an open position, as represented in FIG. 3. When the user again closes the housing 10, the cover 2 is first shut on the base 5 and secondly a force is exerted towards the front of the housing 10, in the opposite direction of the opening direction, until the hook 8 of the cover 2 cooperates with the protuberance 7 of the base 5.

The housing 10 according to embodiments may comprise an elastic element, for example a spring in the grooves of the lateral walls of the base 5, so as to position the plate 3, when no exterior intervention is applied, into a reference position possibly being the initial position.

The elastic element thus make it possible to avoid undesired movements of the plate 3 in the base 5 and contributes to increasing the apparent sturdiness and quality of the housing 10.

1. A housing, comprising:
a cover;
a base;
a plate inserted between said cover and said base, wherein said cover is rotatably articulated relative to the plate by a hinge; and
a locking system fixedly connecting the cover and the base in a closed position, wherein
said plate is slidably mounted on said base so as to permit translation movement of said cover, and a force exerted on the cover causes the plate to side from an initial position towards a second open position, causing the locking system to unlock.

2. The housing according to claim 1, wherein said locking system is formed by a projection formed on said base, which cooperates with a hook formed on said cover.

3. The housing according to claim 1, wherein said base comprises an impression cooperating with a projection of said plate such that said plate slides into said impression.

4. The housing according to claim 1, wherein said housing comprises an elastic element suitable for returning the position of said plate into an initial position.

5. The housing according to claim 1, wherein said hinge comprises an elastic element and/or a retarder for initializing and/or braking the rotation of said cover.

6. The housing according to claim 1 wherein said hinge comprises a stop blocking the rotation of said cover.

7. The housing according to claim 1, wherein said plate comprises at least one compartment suitable for receiving a cosmetic product.

8. The housing according to claim 1, wherein said housing is suitable for receiving one or a plurality of objects, in particular eyewear, watches, jewelry or leather goods.

9. The housing according to claim 1, wherein the plate and/or the cover comprise components of a portable electronic device, in particle a portable phone, a navigator, a personal music player or an mp3 player.

10. The housing according to claim 1, wherein the housing is foound from a plastic material, zamak, metal, alloys or a combination of said materials.
